(19) United States
(12) Patent Application Publication
(10) Pub. No.: US 2022/0137861 A1
(43) Pub. Date: May 5, 2022

(54) METHOD AND DEVICE FOR OPERATING A NONVOLATILE MEMORY DEVICE

(71) Applicant: Robert Bosch GmbH, Stuttgart (DE)

(72) Inventor: Axel Aue, Korntal-Muenchingen (DE)

(21) Appl. No.: 17/434,586

(22) PCT Filed: Mar. 5, 2020
(86) PCT No.: PCT/EP2020/055820

§ 371 Date: Aug. 27, 2021

(30) Foreign Application Priority Data
Mar. 12, 2019 (DE) 102019203351.2

(51) Int. Cl. G06F 3/06

(52) U.S. Cl. CPC G06F 3/0655; G06F 3/0679; G06F 3/0604

(57) ABSTRACT

A method for operating a memory device, including multiple memory cells, for the nonvolatile storage of data, in particular for a motor vehicle. The method includes: checking a predefinable number of memory cells, a check result being obtained, and as a function of the check result, if applicable, programming at least one memory cell of the predefinable number of memory cells, the steps of checking and, if applicable, programming being carried out during operation of the memory device, at least one further unit being able to access the memory device, in particular during operation of the memory device.

### FIELD

The present invention relates to a method for operating a memory device, including multiple memory cells, for the nonvolatile storage of data (nonvolatile memory device).

Moreover, the present invention relates to a device for operating a memory device, including multiple memory cells, for the nonvolatile storage of data.

### SUMMARY

Preferred specific example embodiments relate to a method for operating a memory device, including multiple memory cells, for the nonvolatile storage of data, in particular for a motor vehicle, including the following steps: checking a predefinable number of memory cells, a check result being obtained, and as a function of the check result, if applicable, programming at least one memory cell of the predefinable number of memory cells, the steps of checking and, if applicable, programming being carried out during operation of the memory device. As a result, the content of memory cells of the memory device may advantageously be checked in an efficient manner. In particular, errors or errors that are imminent or possibly occurring in the future may be detected early and remedied if necessary.

In further preferred specific embodiments of the present invention, it is provided that the predefinable number of memory cells encompasses one or multiple memory cells. In further preferred specific embodiments, the steps of checking and/or, if applicable, programming may thus be applied to a single memory cell, for example. In further preferred specific embodiments, the steps of checking and/or, if applicable, programming may be applied to comparatively few memory cells, in particular two to eight memory cells.

In further preferred specific embodiments of the present invention, it is provided that the steps of checking and/or, if applicable, programming are carried out in test cycles, a test cycle encompassing, for example, checking and/or, if applicable, programming at least a single memory cell. For example, in further preferred specific embodiments a single memory cell may be checked in a test cycle. Programming or reprogramming, in particular of an individual memory cell, is thus possible in a targeted manner, as the result of which the reliability of the memory device is increased and the memory cells as a whole are protected, since programming or reprogramming of different, further memory cells, not necessary per se, is dispensed with.

For example, in further preferred specific embodiments of the present invention, a comparatively small predefinable number of memory cells, for example two to eight memory cells, may be checked in a test cycle.

In further preferred specific embodiments of the present invention, it is provided that multiple test cycles are carried out, in particular in chronological succession (for example, directly following one another and/or with (constant or variable) waiting times between two successive test cycles), and which in each case relate, for example, to a single memory cell or a comparatively small predefinable number of memory cells, or also a larger number of memory cells (more than eight, for example) of the memory device.

In further preferred specific embodiments of the present invention, it is also possible for at least two different test cycles to relate to a different number of memory cells in each case.

In further preferred specific example embodiments of the present invention, it is provided that each memory cell of the memory device is subjected to a test cycle at least once, preferably multiple times, in particular during an operating phase of the memory device (operation without interim deactivation).

In further preferred specific embodiments of the present invention, it is provided that the entire memory is tested over a period of minutes, hours, days, weeks, or months, and faulty bit cells are corrected if necessary.

In further preferred specific embodiments of the present invention, it is provided that during operation of the memory device, at least one further unit, for example a processing device such as a processor core of a microcontroller or the like, may access the memory device.

In further preferred specific embodiments of the present invention, it is provided that the step of checking is carried out by a circuit, in particular a hardware circuit, for check sum checking, for example by a bus master such as other processor cores in the system or direct memory access (DMA) enhancements, in particular independently of a microcontroller.

In further preferred specific embodiments of the present invention, it is provided that the checking includes ascertaining at least one first variable that characterizes a data retention of at least one memory cell of the predefinable number of memory cells. It may thus be assessed whether programming or reprogramming is possibly to be carried out after the step of checking, for example because an error or an error that is imminent or possibly occurring in the future has been detected during the checking.

In further preferred specific embodiments of the present invention, it is provided that the first variable includes at least one of the following elements: a) a check sum, associated with the at least one memory cell, of an error-correcting code, b) an electrical charge, and/or a variable characterizing the electrical charge, associated with the at least one memory cell.

In further preferred specific embodiments, measures a), b) may also be combined with one another; for example, the error-correcting code and the variable characterizing the electrical charge are evaluated.

In further preferred specific embodiments of the present invention, it is provided that the method further includes: comparing the first variable to a first threshold value, and if the first variable falls below the first threshold value, programming, in particular reprogramming, the at least one memory cell, no programming, in particular reprogramming, of the at least one memory cell being carried out in particular when the first variable does not fall below the first threshold value or is equal to the first threshold value. In further preferred specific embodiments, the comparison may include, for example, an ascertainment of whether the presence of at least one error is indicated by an error-correcting code.

In further preferred specific embodiments of the present invention, it is provided that the step of programming, in particular reprogramming, is carried out only for that memory cell or those memory cells of the predefinable number of memory cells for which the first variable falls below the first threshold value.

In further preferred specific embodiments of the present invention, it is provided that the step of programming, in particular reprogramming, is carried out for a single memory cell of the predefinable number of memory cells, in particular for the at least one memory cell of the predefinable number of memory cells.

In further preferred specific embodiments of the present invention, it is provided that the steps of checking and/or, if applicable, programming are coordinated, in particular synchronized, with another operation of the memory device, in particular with possible accesses to the memory device by the further unit, in particular in such a way that with regard to the checking and/or, if applicable, the programming, no access conflicts with the possible accesses by the further unit occur.

In further preferred specific embodiments of the present invention, it is provided that a time window is ascertained in which no accesses by the further unit to the memory device, in particular to at least the predefinable number of memory cells, are carried out, and/or for which no accesses by the further unit to the memory device, in particular to at least the predefinable number of memory cells, are planned, in particular the steps of checking and/or, if applicable, programming being carried out in the time window.

In further preferred specific embodiments of the present invention, it is provided that the step of programming, in particular reprogramming, is carried out for a single memory cell of the predefinable number of memory cells, in particular for the at least one memory cell of the predefinable number of memory cells.

Further preferred specific embodiments of the present invention relate to a device for operating a memory device, including multiple memory cells, for the nonvolatile storage of data, in particular for a motor vehicle, the device being designed to carry out the following steps: checking a predefinable number of memory cells, a check result being obtained, and as a function of the check result, if applicable, programming at least one memory cell of the predefinable number of memory cells, the steps of checking and, if applicable, programming being carried out during operation of the memory device, it being possible for at least one further unit to access the memory device, in particular during operation of the memory device.

In further preferred specific example embodiments of the present invention, it is provided that the device is designed to carry out the method according to the specific embodiments.

In further preferred specific example embodiments of the present invention, it is provided that the device is at least partially, preferably completely, integrated into the memory device, for example on the same semiconductor substrate as the memory device.

In further preferred specific example embodiments of the present invention, it is provided that the memory device is a flash memory, in particular a flash EEPROM, or a phase change memory (PCM), a ferroelectric random access memory (FRAM), a resistive random access memory (RRAM), a conductive bridging RAM (CBRAM), or a magnetoresistive random access memory (MRAM).

In further preferred specific example embodiments of the present invention, the method according to the specific embodiments may advantageously be applied for all memories or memory types when there is insufficient intrinsic data security (for a predefinable intended purpose, for example).

Further advantages of the method according to the specific embodiments may include that a) correctable errors are corrected, b) the intrinsic error rate from the system viewpoint drops significantly, and thus c) an improved basis for safeguarding according to the safety requirements may be provided.

In further preferred specific example embodiments of the present invention, it is provided that the at least one memory cell has a memory capacity of 1 bit, i.e., may assume, for example, two different states. In further preferred specific embodiments, the method may also be applied for 3 or more bits per cell, and is likewise advantageously applicable in multilevel cell memories, which in principle have a higher intrinsic error rate.

In further preferred specific example embodiments of the present invention, it is provided that the at least one memory cell has a memory capacity of greater than 1 bit, for example 2 bits, i.e., may assume, for example, four different states.

Further preferred specific example embodiments of the present invention relate to a system that includes at least one memory device including multiple memory cells, and at least one device according to the specific embodiments.

In further preferred specific example embodiments of the present invention, it is provided that the system is a control unit for a motor vehicle.

Further preferred specific example embodiments of the present invention relate to a use of the method according to the specific embodiments and/or of the device according to the specific embodiments and/or of the system according to the specific embodiments for at least occasionally checking and/or programming, in particular reprogramming and/or refreshing, at least one memory cell of a or the memory device.

Further features, application options, and advantages of the present invention result from the following description of exemplary embodiments of the present invention, illustrated in the figures. All described or illustrated features, alone or in any arbitrary combination, constitute the subject matter of the present invention, regardless of their wording or illustration in the description or figures, respectively.

### BRIEF DESCRIPTION OF THE DRAWINGS

FIG. 1 schematically shows a block diagram of a memory device according to preferred specific embodiments of the present invention.

FIG. 2 schematically shows a simplified flowchart of a method according to further preferred specific embodiments of the present invention.

FIG. 3 schematically shows a simplified flowchart of a method according to further preferred specific embodiments of the present invention.

FIG. 4 schematically shows a simplified flowchart of a method according to further preferred specific embodiments of the present invention.

FIG. 5 schematically shows a simplified flowchart of a method according to further preferred specific embodiments of the present invention.

FIG. 6 schematically shows a time diagram according to further preferred specific embodiments of the present invention.

FIG. 7 schematically shows a block diagram according to further preferred specific embodiments of the present invention.

### DETAILED DESCRIPTION OF EXAMPLE EMBODIMENTS

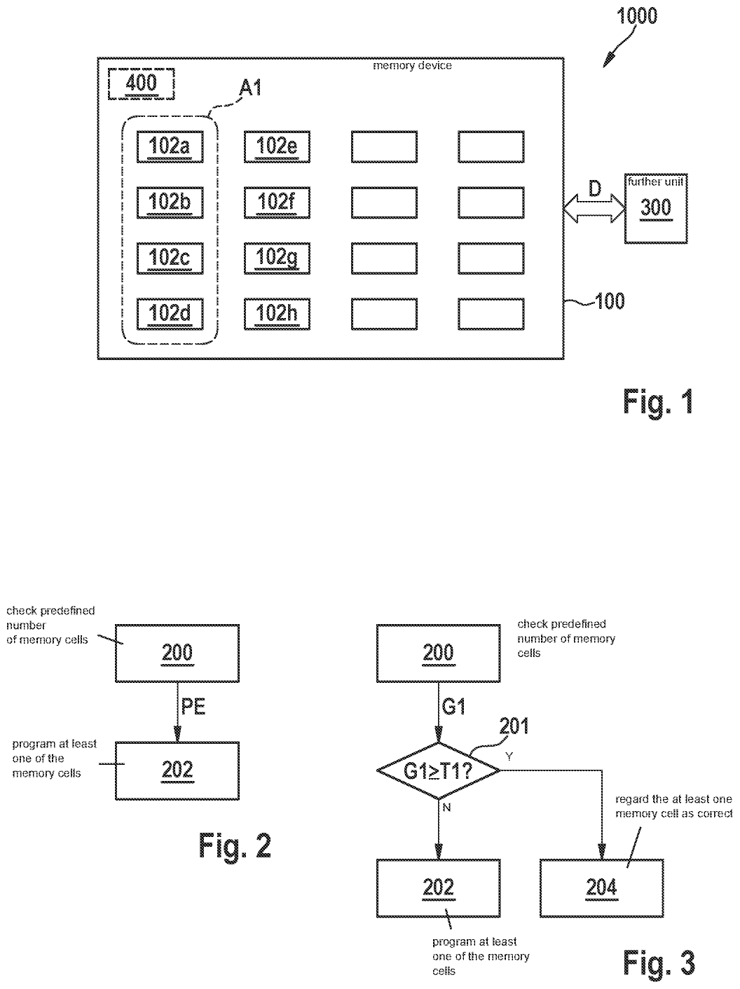

FIG. 1 schematically shows a block diagram of a memory device 100 according to preferred specific embodiments. Memory device 100 includes multiple memory cells, collectively denoted by reference numeral 102. Some of memory cells 102 are also individually denoted by reference numerals 102a, 102b, . . . , 102h. Memory device 100 is provided for the nonvolatile storage of data. For example, in further preferred specific embodiments, memory device 100 may be provided for use in a motor vehicle, for example associated with a control unit for the motor vehicle.

In further preferred specific embodiments, it is provided that during operation of memory device 100, at least one further unit 300, for example a processing device such as a processor core of a microcontroller or the like, for example of the stated control unit, may access memory device 100, in particular may write data D into memory device 100 and/or read out data from memory device 100.

In further preferred specific embodiments, it is provided that memory device 100 is a semiconductor memory, in particular a flash memory, in particular a flash EEPROM, or a phase change memory (PCM) or a magnetoresistive random access memory (MRAM). Further technologies for providing memory cells 102 for the nonvolatile storage of information are likewise usable in further preferred specific embodiments.

In further preferred specific embodiments, it is provided that at least one memory cell, in particular all memory cells 102, has/have a memory capacity of 1 bit, i.e., may assume, for example, two different states. In further preferred specific embodiments, it is provided that at least one memory cell, in particular all memory cells 102, has/have a memory capacity of greater than 1 bit, for example 2 bits, i.e., may assume, for example, four different states.

Preferred specific embodiments relate to a method for operating memory device 100, including the following steps (cf. the flowchart from FIG. 2): checking 200 a predefinable number A1 (FIG. 1) of memory cells, a check result PE (FIG. 2) being obtained, and as a function of check result PE, if applicable, programming 202 at least one memory cell 102a, 102b, 102c, 102d of predefinable number A1 of memory cells. Programming 202 thus takes place optionally, in particular as a function of check result PE.

In further preferred specific embodiments, the steps of checking 200 and (if applicable) programming 202 are carried out during operation of memory device 100, for example while memory device 100 is configured to receive data from further unit 300 (FIG. 1) and store it, and/or to process reading accesses to at least some of memory cells 102 by the further unit. As a result, the content of memory cells 102 of memory device 100 may be advantageously checked in an efficient manner, in particular without operation of memory device 100 being limited with regard to exchange D of data with further unit 300.

In further preferred specific embodiments, it is provided that predefinable number A1 of memory cells includes one or multiple memory cells. In the present case, by way of example a group of four memory cells 102a, 102b, 102c, 102d is combined to form predefinable number A1 in FIG. 1. Thus, in the present case, for example the steps of checking 200 and/or, if applicable, programming 202 may be applied, for example, to the four memory cells 102a, 102b, 102c, 102d. As a result, in further preferred specific embodiments, accesses (reading and/or writing) by further unit 300 (FIG. 1) to other memory cells 102e, 102f, . . . of memory device 100 are not limited.

In further preferred specific embodiments, the steps of checking 200 and/or, if applicable, programming 202 may also be applied to a single memory cell 102a, for example. In further preferred specific embodiments, the steps of checking and/or, if applicable, programming may be applied to comparatively few memory cells, in particular two to eight memory cells.

In further preferred specific embodiments, it is provided that the steps of checking 200 and/or, if applicable, programming 202 are carried out in test cycles, a test cycle encompassing, for example, checking 200 and/or, if applicable, programming 202 at least a single memory cell 102a. For example, in further preferred specific embodiments a single memory cell 102a may be checked in a test cycle. Programming or reprogramming, in particular of an individual memory cell 102a, is thus possible in a targeted manner, as the result of which the reliability of memory device 100 is increased and memory cells 102 as a whole are protected, since programming or reprogramming, not required per se, of different, further memory cells 102b, 102c, 102d, etc., as in conventional memory devices which necessarily require, for example, blockwise programming of a plurality of memory cells (even if not all, or only some, or only a single memory cell of the block in question were to be programmed), is dispensed with.

For example, in further preferred specific embodiments a comparatively small predefinable number of memory cells, for example two to eight memory cells, may be checked in a test cycle.

In further preferred specific embodiments, it is provided that multiple test cycles are carried out, in particular in chronological succession (for example, directly following one another and/or with (constant or variable) waiting times between two successive test cycles), which in each case relate, for example, to a single memory cell 102a or a comparatively small predefinable number of memory cells, or also a larger number of memory cells (more than eight, for example) of the memory device.

In further preferred specific embodiments, it is also possible for at least two different test cycles to relate to a different number of memory cells in each case.

In further preferred specific embodiments, it is provided that each memory cell 102 of memory device 100 (FIG. 1) is subjected to a test cycle at least once, preferably multiple times, in particular during an operating phase (operation without interim deactivation) of memory device 100 (for example, including checking 200 (FIG. 2) and, if applicable, subsequent programming 202).

In further preferred specific embodiments (cf. the flowchart from FIG. 3), it is provided that checking 200 includes ascertaining at least one first variable G1 that characterizes a data retention of at least one memory cell 102a of predefinable number A1 of memory cells. It may thus be assessed in a particularly accurate manner whether programming 202 or reprogramming (i.e., programming anew using the same content or a new, corrected content, as has been ascertained, for example, after the application of an error-correcting code, for example ECC) is possibly to be carried out after the step of checking 200.

In further preferred specific embodiments, it is provided that first variable G1 includes at least one of the following elements: a) a check sum, associated with the at least one memory cell 102a, of an error-correcting code, b) an electrical charge, and/or a variable characterizing the electrical charge, associated with the at least one memory cell 102a.

If, for example, the check sum shows that an error is present in the range of predefinable number A1 of memory cells, for example of memory cell 102a, in further preferred specific embodiments a correct content of memory cell 102a in question may be ascertained with the aid of the error-correcting code, for example, and the step of (re)programming 202 may be carried out in order to refresh memory cell 102a with the proper data content. First variable G1 may, for example, likewise be a two-value variable that indicates whether or not an error is present. Accordingly, comparison 201 may easily be dispensed with.

In further preferred specific embodiments, for example the electrical charge of a semiconductor component (for example, a floating gate electrode of a flash memory cell) may be evaluated as first variable G1.

In further preferred specific embodiments, it is provided that the method further includes: comparing 201 (FIG. 3) the first variable to a first threshold value T1, and if first variable G1 falls below first threshold value T1, programming 202, in particular reprogramming, the at least one memory cell 102a. As a result, a reliable correction of a memory cell 102a that is possibly already faulty, or refreshing a memory cell 102a that is at risk of becoming faulty in the future (for example, by reducing the electrical charge on the floating gate electrode of a flash memory cell), is possible, so that future read accesses could result, for example, in an incorrectly read out data value (for example, “0” instead of “1”).

In further preferred specific embodiments, it is provided that no programming 202, in particular reprogramming, of the at least one memory cell 102a is carried out when first variable G1 does not fall below first threshold value T1 or is equal to the first threshold value. In this case, the at least one memory cell 102a is regarded as correct, and the method branches into step 204 according to FIG. 3, which represents, for example, an end of test cycle 200, 201 at that moment. After step 204, in further preferred specific embodiments, for example a further test cycle may take place, for example for a further predefinable number of (preferably different) memory cells 102e, 102f, 102g, 102h (FIG. 1).

In further preferred specific embodiments, it is provided that the step of programming 200, in particular reprogramming, is carried out only for that memory cell or those memory cells of predefinable number of memory cells A1 for which first variable G1 falls below first threshold value T1. As a result, writing, which requires resources and possibly places a burden on the memory cell(s) in question, is carried out only for those memory cells that require programming or reprogramming in the sense of a refresh, but not for those memory cells for which these steps 200 are not (already) necessary. As a result, it is furthermore advantageous that wear on the memory cells (for example, damage to an oxide layer that insulates the floating gate electrode in the case of writing or programming of flash memory cells) is reduced.

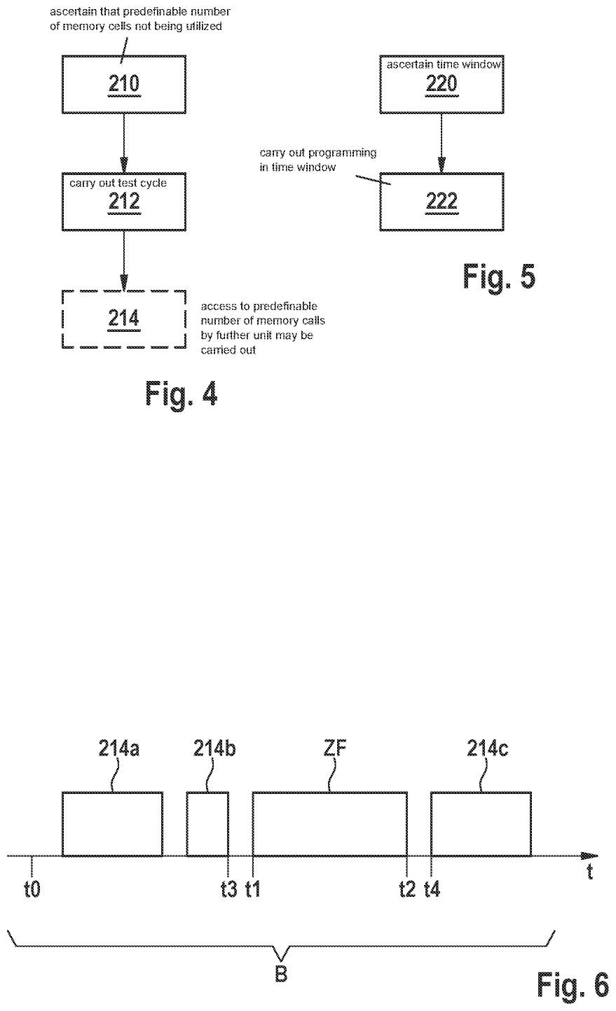

In further preferred specific embodiments, it is provided that the steps of checking 200 and/or, if applicable, programming 202 are coordinated, in particular synchronized, with another operation of memory device 100, in particular with possible accesses D to memory device 100 by further unit 300 (FIG. 1), in particular in such a way that no access conflicts with the possible accesses D by further unit 300 occur with regard to checking 200 and/or (if applicable) programming 202. In this respect, FIG. 4 shows an example of a flowchart according to further preferred specific embodiments. The above-described coordination or synchronization takes place in step 210, in which in the present case it is ascertained, for example, that memory device 100 at that time is not acted on by further unit 300 in such a way, for example, that predefinable number A1 of memory cells is utilized by further unit 300. Therefore, steps 200 of checking and, if applicable, programming 202, and thus a test cycle for predefinable number A1 of memory cells, may be carried out in step 212. After completion of this test cycle, accesses to predefinable number A1 of memory cells by further unit 300 may once again be carried out (cf. optional step 214 from FIG. 4).

In further preferred specific embodiments (cf. FIG. 5), it is provided that a time window is ascertained (cf. step 220) in which no accesses by further unit 300 (FIG. 1) to memory device 100, in particular to at least predefinable number A1 of memory cells, are carried out, and/or for which no accesses by further unit 300 to memory device 100, in particular to at least predefinable number A1 of memory cells, are planned, in particular the steps of checking 200 and/or, if applicable, programming 202 being carried out in the time window (cf. step 222 from FIG. 5).

In this regard, FIG. 6 shows a time diagram. An operating phase of memory device 100 is denoted by reference symbol B. Further unit 300 may access memory device 100 during entire operating phase B. Beginning at point in time to, two accesses 214a, 214b by further unit 300 to memory device 100, for example to memory cells 102a, . . . , 102d, are shown which last up to point in time t3. Beginning at point in time t4, a further access 214c to memory device 100 by further unit 300 takes place, for example access once again to memory cells 102a, . . . , 102d. In further preferred specific embodiments, a time window ZF between points in time t1, t2, where t1>t3 and t2<t4, is ascertained in which the method may be carried out according to the specific embodiments (cf. FIG. 2, for example), or one or multiple corresponding test cycles, in particular with regard to memory cells 102a, . . . , 102d, may be carried out, as the result of which accesses 214a, 214b, 214c are not adversely affected.

Further preferred specific embodiments relate to a device for operating memory device 100 for the nonvolatile storage of data, in particular for a motor vehicle, the device being designed to carry out the method according to the specific embodiments. In further preferred specific embodiments, it is provided that the device is integrated at least partially, preferably completely, into memory device 100 (cf. element 400 from FIG. 1). For example, the functionality of device 400 may also be achieved by an existing memory controller (not shown) of memory device 100, which may be appropriately expanded for this purpose.

Further preferred specific embodiments relate to a system 1000 (FIG. 1) including at least one memory device 100 that includes multiple memory cells 102, and at least one device 400 according to the specific embodiments. In further preferred specific embodiments, it is provided that system 1000 is a control unit for a motor vehicle. For example, further unit 300 may be a processor core of a processing device of control unit 1000.

Further preferred specific embodiments relate to a use of the method according to the specific embodiments and/or of device 400 according to the specific embodiments and/or of system 1000 according to the specific embodiments for at least occasionally checking and/or programming, in particular reprogramming and/or (re)freshing, at least one memory cell 102a of a or the memory device 100.

Further advantageous aspects and specific embodiments are described below, which according to yet further preferred specific embodiments are in each case combinable, alone or in combination with one another, with any of the specific embodiments described above.

Further preferred specific embodiments allow a refresh of individual memory cells 102a, 102b, . . . during operation of system 1000, in particular without having to provide memory blocks, in particular additional memory blocks.

In further preferred specific embodiments, preferably only the memory cells that have lost charge are programmed or reprogrammed, as the result of which the stress on other/neighboring cells of the memory device is minimized. The stress and thus the failure rate for other cells is reduced, in particular compared to conventional methods based on block-based programming using additional blocks.

In further preferred specific embodiments, the method (cf. FIG. 2, for example) is carried out during operation of system 1000, in particular without (additional) blocks; this may advantageously be made possible by coupling the process according to FIG. 2, for example, to running system 1000 or to the accesses by further unit 300.

In further preferred specific embodiments, the method according to the specific embodiments (cf. steps 200, 202 according to FIG. 2, for example) may be advantageously used in conjunction with double error correction triple error detection (DECTED) ECC, for example to reliably reset an error counter for a range from 1 to 0 that is safeguarded by an error-correcting code, for example ECC, before occurrence of a third, uncorrectable error. In further preferred specific embodiments, the step of checking 200 may thus include the application of a DECTED ECC method.

Since the method, according to at least some preferred specific embodiments, may be carried out during ongoing operation of memory device 100 or of system 1000:—It is easier to set up a Safety Automotive Safety Integrity Level (ASIL) D system, since the initial error rate for the bit error consideration is much lower,—The risk of failures is lower, since it is no longer necessary to wait until control unit 1000 is in overrun mode or in the start phase in order to refresh (reprogram); for example, an automobile travels for several hours,—For memory devices 100 according to further preferred specific embodiments, the intrinsic data retention time at elevated temperatures and fairly long run times is smaller in the ppm range for a number of cells, and therefore may be refreshed beforehand without failure,—It is possible to use new nonvolatile memory technologies, for example with shorter data retention times.

In further preferred specific embodiments, error-correcting codes ECC are used with triple bit error detection and double bit error correction (DECTED ECC).

In further preferred specific embodiments, other methods may alternatively or additionally be used, for example, for determining the instantaneous charge of a memory cell, for example, the conventional margin read methods.

Further preferred specific embodiments allow, for example during ongoing operation of system 1000, a charge of the bits or the memory content of memory cells 102 to be checked, in particular continuously, and/or an error-correcting code (ECC) to be checked, in particular continuously, for example until an error is visible and/or until a data retention of the memory cell that is no longer sufficient is establishable (charge too low, for example), it being possible for such an error or the memory cell in question to then be directly programmed or reprogrammed, using the correct data value. Since in particular in DECTED ECC methods it is also possible to correct a second error, the probability of failure of system 1000 is thus much lower.

In further preferred specific embodiments, in running system 1000 a search is made for states in which it is ensured that for a predefinable time (for example, 30 μs (microseconds) for PCM memory cells) it is not necessary to access the memory (by further unit 300, for example); cf. also time window ZF depicted in FIG. 6 as an example. In further preferred specific embodiments, this time window is utilized to reprogram the memory cell, which is faulty or conspicuous due to its presumed low remaining data retention (low charge, for example).

In further preferred specific embodiments, a correction of memory cells that are conspicuous or detected as faulty takes place before a second or third cell in same area A1 (FIG. 1) that is safeguarded by ECC, for example, in particular DECTED ECC, becomes defective.

In further preferred specific embodiments, preferably the entire memory area of memory device 100, in particular all memory cells 102, is/are checked over time, for example in the form of test cycles, each of which considers only one or a few memory cells, as the result of which shorter data retention times (for example, due to high temperatures, and/or memory cell technologies with inherently low data retention, such as flash memory) may advantageously be compensated for. For example, in further preferred specific embodiments the method may be carried out according to the specific embodiments (cf. steps 200, 202 from FIG. 2, for example) at a rate of 120 bytes per second, it being possible, for example, for a memory area of 8 megabytes (MB) to be checked at least once per day, and, if applicable, to be (re)programmed or refreshed.

In further preferred specific embodiments, error-correcting codes together with margin read techniques may also be used, for example for the step of checking 200 (FIG. 2).

In further preferred specific embodiments, it is also possible for (only) margin read techniques to be used for the step of checking 200 (FIG. 2). In these variants, an evaluation or provision of an error-correcting code is not necessary.

In further preferred specific embodiments, single error correction and double error detection (SECDED) techniques may also be used, in which one error may be corrected and two errors may be detected.

In further preferred specific embodiments, error-correcting codes which allow a correction of more than two bits may also be used for checking 200 (FIG. 2), among other things.

In further preferred specific embodiments, the method according to FIG. 2 may be used, for example, in a start-up or boot of system or control unit 1000.

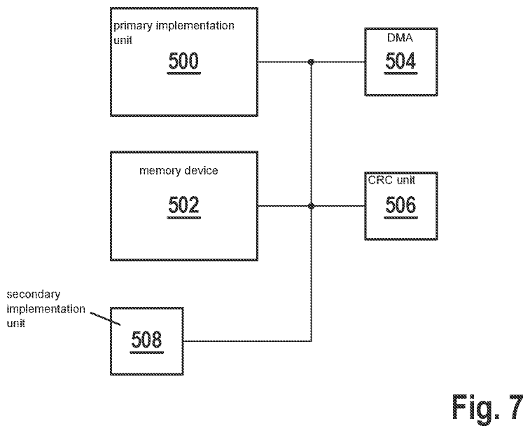

FIG. 7 schematically shows a block diagram according to further preferred specific embodiments. A primary implementation unit 500 and a memory device 502 associated with primary implementation unit 500 are depicted. Primary implementation unit 500 is, for example, a first processor core of a microcontroller, for example. In further preferred specific embodiments, a direct memory access (DMA) unit 504 is provided, which in a conventional manner may read out data from memory device 502 and/or write data into memory device 502, in particular without (assistance from) implementation unit 500. In further preferred specific embodiments, a check sum unit (CRC unit) 506 is provided which, if applicable, in conjunction with DMA unit 504, may access data, in particular a predefinable number A1 (FIG. 1) of memory cells of memory device 502, and in particular may carry out the step of checking 200 (FIG. 2) and/or programming 202. At least one secondary implementation unit 508 (a further processor core, for example) is optionally provided, which according to further preferred specific embodiments, the same as for the primary implementation unit, may load and/or execute program code and/or data from the memory device (for example, also utilizing DMA unit 504). According to further preferred specific embodiments, at least one of implementation units 500, 508 is designed to carry out the method according to the specific embodiments (cf. FIG. 2, for example). According to further preferred specific embodiments, check sum unit 506 and/or DMA unit 504 are/is designed to carry out the method according to the specific embodiments (cf. FIG. 2, for example).

1-15. (canceled)

16. A method for operating a memory device, including multiple memory cells, for the nonvolatile storage of data, for a motor vehicle, the method comprising the following steps:
checking a predefinable number of the memory cells to obtain a check result; and
programming, as a function of the check result, at least one memory cell of the predefinable number of the memory cells;
wherein the steps of checking and programming are carried out during operation of the memory device, at least one further unit being able to access the memory device during operation of the memory device, and wherein the steps of checking and/or programming are being coordinated with another operation of the memory device with possible accesses to the memory device by the further unit in such a way that with regard to the checking and/or the programming, no access conflicts with the possible accesses by the further unit occur.

17. The method as recited in claim 16, wherein the checking includes ascertaining at least one first variable that characterizes a data retention of at least one memory cell of the predefinable number of the memory cells.

18. The method as recited in claim 17, wherein the first variable includes at least one of the following elements: a) a check sum, associated with the at least one memory cell, of an error-correcting code, b) an electrical charge, and/or a variable characterizing an electrical charge, associated with the at least one memory cell.

19. The method claim 17, further comprising:
comparing the first variable to a first threshold value, and when the first variable falls below the first threshold value, programming the at least one memory cell, wherein no programming of the at least one memory cell is carried out when the first variable does not fall below the first threshold value or is equal to the first threshold value.

20. The method as recited in claim 19, wherein the programming, is carried out only for that memory cell or those memory cells of the predefinable number of the memory cells for which the first variable falls below the first threshold value.

21. The method as recited in claim 16, wherein the step of programming is carried out for at least one memory cell of the predefinable number of the memory cells.

22. The method as recited in claim 16, wherein a time window is ascertained in which no accesses by the further unit at least the predefinable number of the memory cells are carried out, and/or for which no accesses by the further unit to the memory device to at least the predefinable number of memory cells are planned, and where the steps of checking and/or programming being carried out in the time window.

23. The method as recited in claim 16, wherein the step of programming is carried out for the at least one memory cell of the predefinable number of the memory cells.

24. A device configured to operate a memory device, including multiple memory cells for the nonvolatile storage of data for a motor vehicle, the device being configured to:
check a predefinable number of the memory cells to obtain a check result; and
program, as a function of the check result, at least one memory cell of the predefinable number of the memory cells;
wherein the check and the programming are carried out during operation of the memory device, it being possible for at least one further unit to access the memory device during the operation of the memory device, wherein the device is configured to coordinate the check and/or the programming with another operation of the memory device, with possible accesses to the memory device by the further unit, in such a way that with regard to the check and/or the programming, no access conflicts with the possible accesses by the further unit occur.

25. The device as recited in claim 24, wherein the check includes ascertainment of at least one first variable that characterizes a data retention of at least one memory cell of the predefinable number of memory cells.

26. The device as recited in claim 24, wherein the device is at least partially integrated into the memory device.

27. A system, comprising:
at least one memory device including multiple memory cells; and
at least one device configured to operate the memory device, the device being configured to:
check a predefinable number of the memory cells to obtain a check result, and
program, as a function of the check result, at least one memory cell of the predefinable number of memory cells,
wherein the check and the programming are carried out during operation of the memory device, it being possible for at least one further unit to access the memory device during the operation of the memory device, wherein the device is configured to coordinate the check and/or the programming with another operation of the memory device, with possible accesses to the memory device by the further unit, in such a way that with regard to the check and/or the programming, no access conflicts with the possible accesses by the further unit occur.

28. The system as recited in claim 27, wherein the system is a control unit for a motor vehicle.

29. The method as recited in claim 16, wherein the method is used or at least occasionally checking and/or programming and/or refreshing at least one memory cell of the memory device.
